(19) United States
(12) Patent Application Publication
(10) Pub. No.: US 2015/0041336 A1
(43) Pub. Date: Feb. 12, 2015

(54) POTENTIOSTAT REFERENCE ELECTRODE INTERFACE

(71) Applicant: Xagenic Inc., Toronto (CA)

(72) Inventor: Wen Chan, Ontario (CA)

(21) Appl. No.: 14/454,694

(22) Filed: Aug. 7, 2014

Related U.S. Application Data
(60) Provisional application No. 61/863,400, filed on Aug. 7, 2013.

(51) Int. Cl. G01N 27/327; H05K 9/00

(52) U.S. Cl. CPC G01N 27/3274; G01N 27/3271; H05K 9/0071
USPC 205/792; 327/552; 204/403.01

(57) ABSTRACT

A method for shielding an electrical signal without substantially degrading the system speed or substantially increasing the bulk of the system is provided. The method includes applying a first signal to a conductor coupled to the electrode, applying a second signal to a shield substantially surrounding the conductor, blocking electrical interference to the first signal, and increasing an effective impedance on the electrode coupled to the conductor. The second signal may be a buffered and compensated version of the first signal.

### CROSS-REFERENCE TO RELATED APPLICATIONS

This application claims the benefit of U.S. Provisional Application No. 61/863,400, filed on Aug. 7, 2013, which is hereby incorporated herein by reference in its entirety.

### BACKGROUND

The reference electrode on a potentiostat system is highly susceptible to electrical interference from external sources. Preventing electrical interference from external sources is especially important when the size of the reference electrode is reduced and/or when miniaturization is desired, for example, in medical diagnostic devices. Various designs use an external faraday cage and/or shielded coaxial cables to decrease interference on the reference signal. Because the reference electrode has a very high impedance, the capacitance added when shielding an electrical signal from external interference has the side effect of slowing down the potentiostat system, and thus the performance of the diagnostic device. Thus, alternative systems and methods for reducing external influences on an electrical signal and increasing impedance on a reference electrode in a potentiostat system could be beneficial for diagnostic devices.

Biomarker analysis based on electronic readout has long been cited as a promising approach that would enable a new family of chip-based devices with appropriate cost and sensitivity for medical diagnostic devices (Drummond et al., Nat. Biotechnol. 21:1192, Katz et al., Electroanalysis 15:913). The sensitivity of electronic readout is in principle sufficient to allow direct detection of small numbers of analyte molecules with simple instrumentation. However, despite tremendous advances in this area as well as related fields working towards new diagnostics (Clack et al., Nat. Biotechnol. 26:825, Geiss et al., Nat. Biotechnol. 26:317, Hahm et al., Nano Lett. 4:51, Munge et al, Anal. Chem. 77:4662, Nicewarner-Pena et al., Science 294:137, Park et al, Science 295:1503, Sinensky et al., Nat. Nano. 2:653, Steemers et al., Nat. Biotechnol. 18:91, Xiao et al., J Am. Chem. Soc. 129:11896, Zhang et al., Nat. Nano. 1:214, Zhang et al., Anal. Chem. 76:4093, Yi et al., Biosens. Bioelectron. 20:1320, Ke et al., Science 319:180, Armani et al., Science 317:783), current multiplexed chips have yet to achieve direct electronic detection of biomarkers in cellular and clinical samples. The challenges that have limited the implementation of such devices primarily stem from the difficulty of obtaining very low detection limits in the presence of high background noise levels present when complex biological samples are assayed, and the challenge of generating multiplexed systems that are highly sensitive and specific. Therefore, systems, methods, and devices that improve the signal to noise ratio of such detection devices is desirable.

### SUMMARY

Disclosed herein are systems, devices and methods for shielding an electrical signal without substantially degrading the system speed, or substantially increasing the bulk of the system. In one aspect, a method for transmitting a signal on a transmission line includes applying a first signal to a conductor, applying a second signal to a shield substantially surrounding the conductor, blocking electrical interference to the first signal, and increasing the effective impedance seen by an electrode coupled to the conductor, while decreasing the effects of capacitive loading. In certain implementations, the second signal is a buffered and compensated version of the first signal. The second signal may be created using compensation circuitry by measuring the first signal on the conductor, amplifying the first signal, removing at least one high frequency component from the first signal, and phase shifting the first signal. In certain implementations, the method includes substantially reducing or eliminating a potential difference between the conductor and the shield. In certain implementations, the second signal is applied by a low impedance source.

In another aspect, a method for detecting a target in a sample using a point-of care diagnostic device is provided wherein the diagnostic device includes a potentiostat that provides active shielding for one or more reference electrodes in the potentiostat. In certain implmentations, the signal path comprises a reference electrode in a potentiostat. In some implementations, the signal path comprises a high impedance transducer interface. In certain implementations the device uses the methods disclosed herein (and variations thereof).

In yet another aspect, a signal transmission system is provided, the signal transmission system including a transmission line including a conductor and a shield substantially surrounding the conductor, first and second compensation circuits coupled between the conductor and the shield, and a unity gain buffer coupled between the first and second compensation circuits. In sonic implementations, the transmission system includes an electrode coupled to the conductor. in certain implementations, the first compensation circuit comprises a first resistor and a first capacitor capable of removing gain at high frequencies from a first signal. In some implementations, the second compensation circuit comprises a second resistor and a second capacitor capable of phase shifting the first signal, In certain implementations, the transmission line is a coaxial cable. In certain implementations, the shield comprises a braided cylinder. Ire certain implementations, the shield comprises a faraday cage. In some implementations, a point-of-care diagnostic device is provided that includes a potentiostat that includes the signal transmission system described above, thereby providing active shielding for one or more reference electrodes in the potentiostat.

### BRIEF DESCRIPTION OF THE DRAWINGS

The foregoing and other objects and advantages will be apparent upon consideration of the following detailed description, taken in conjunction with the accompanying drawings, in which like reference characters refer to like parts throughout, and in which:

FIG. 1 depicts a block diagram of an illustrative 3-electrode potentiostat system;

FIG. 2 depicts a block diagram of an illustrative transmission line system;

FIG. 3 depicts a circuit diagram of an illustrative compensation circuit;

FIG. 4 depicts an illustrative cartridge system for receiving, preparing, and analyzing a biological sample;

FIG. 5 depicts an illustrative cartridge for an analytical detection system;

FIG. 6 depicts an illustrative automated testing system;

FIG. 7 depicts a voltage-current curve measured without active shielding;

FIG. 8 depicts a voltage-current curve measured with active shielding;

FIG. 9 depicts representative electrocatalytic detection signals;

FIG. 10 depicts an analysis chamber with a pathogen sensor and a host sensor;

FIG. 11 depicts an analysis chamber with a pathogen sensor and a host sensor; and

FIG. 12 depicts an additional embodiment of an analysis chamber.

### DETAILED DESCRIPTION

To provide an overall understanding of the systems, devices, and methods described herein, certain illustrative embodiments will be described. It is to be understood that the systems, devices, and methods disclosed herein, while shown for use in diagnostic systems for bacterial diseases such as Chlamydia, may be applied in other applications including, but not limited to, detection of other bacteria, viruses, fungi, prions, plant matter, animal matter, protein, RNA sequences, DNA sequences, as well as cancer screening and genetic testing, including screening for genetic traits and disorders.

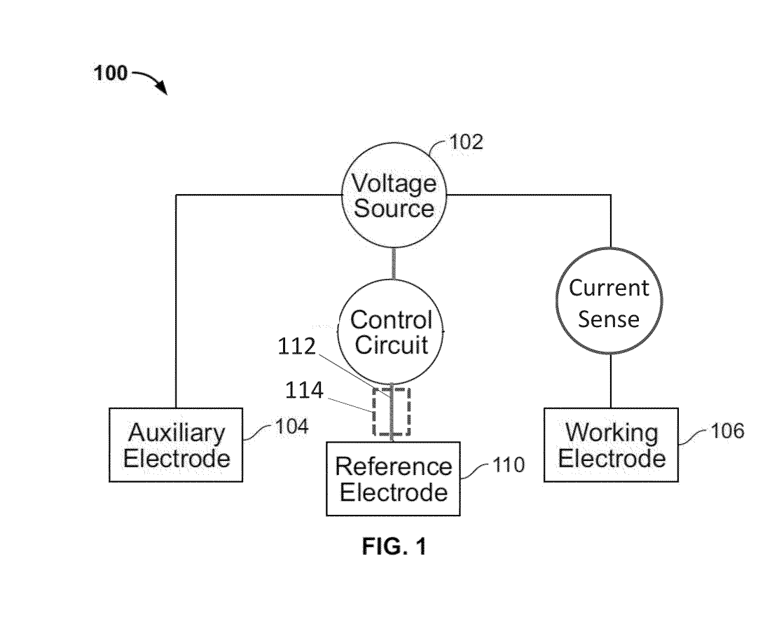

FIG. 1 depicts a block diagram of a 3-electrode potentiostat system 100. The potentiostat system 100 may be used, for example, in a diagnostic device. The potentiostat system 100 comprises a voltage source 102 coupled between an auxiliary electrode 104 and a working electrode 106, and a control circuit 108 coupled between a reference electrode 110 and the working electrode 106. During operation, the potentiostat system may function to maintain the potential of the working electrode 106 at a pre-determined level with respect to the reference electrode 110 by adjusting the controlled voltage source 102 at the auxiliary electrode 104. The transmission line 112 connected to the reference electrode 110 (highlighted with a dashed box 114 in FIG. 1) carries a reference signal and may be shielded to prevent interference with the reference signal by outside influences. For example, the transmission line 112 may include a coaxial cable with an inner conductor substantially surrounded by an outer shield. In some embodiments, the outer shield may be braided or may include a faraday cage. The outer shield may be used to block interference with the reference signal carried on the inner conductor of the coaxial cable. In conventional designs, the outer shield may be grounded. However, when the outer shield is grounded, the capacitance created between the outer shield and the inner conductor loads the reference electrode output and may slow down detection by the diagnostic device.

In this disclosure, slowing of the diagnostic system may be prevented by inhibiting a capacitance between the inner conductor and the outer shield from being charged or discharged. A suitably buffered and compensated version of the reference signal is applied to the outer shield instead of connecting the outer shield to ground potential. As a result, substantially no potential difference exists between the reference signal on the inner conductor and the outer shield. Furthermore, the impedance on the outer shield is made very low so that external influences couple to the outer shield and do not make their way to the inner conductor. Reducing the potential difference between the outer shield and the inner conductor can increase the effective impedance on the reference electrode and improve performance of the associated diagnostic device.

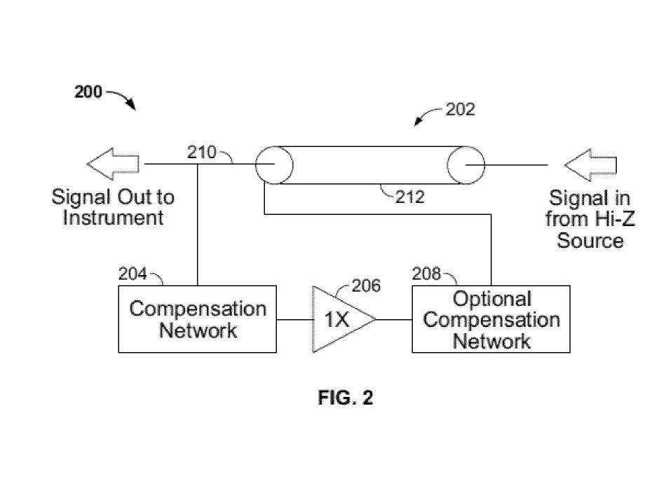

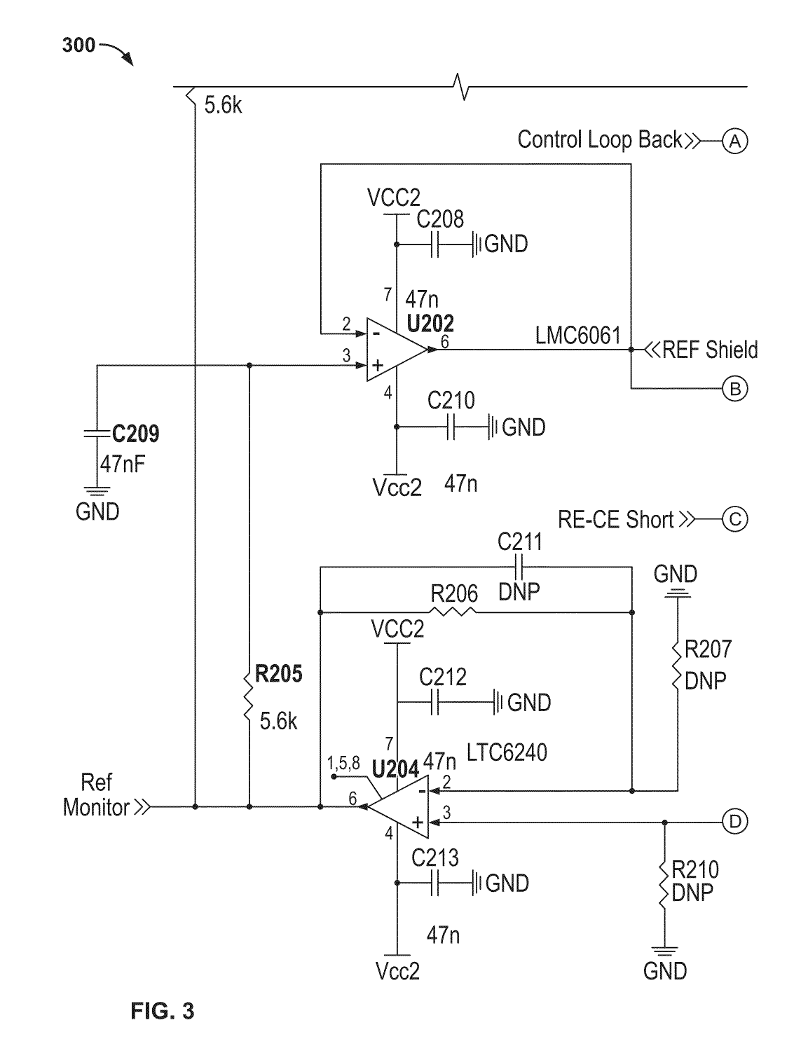

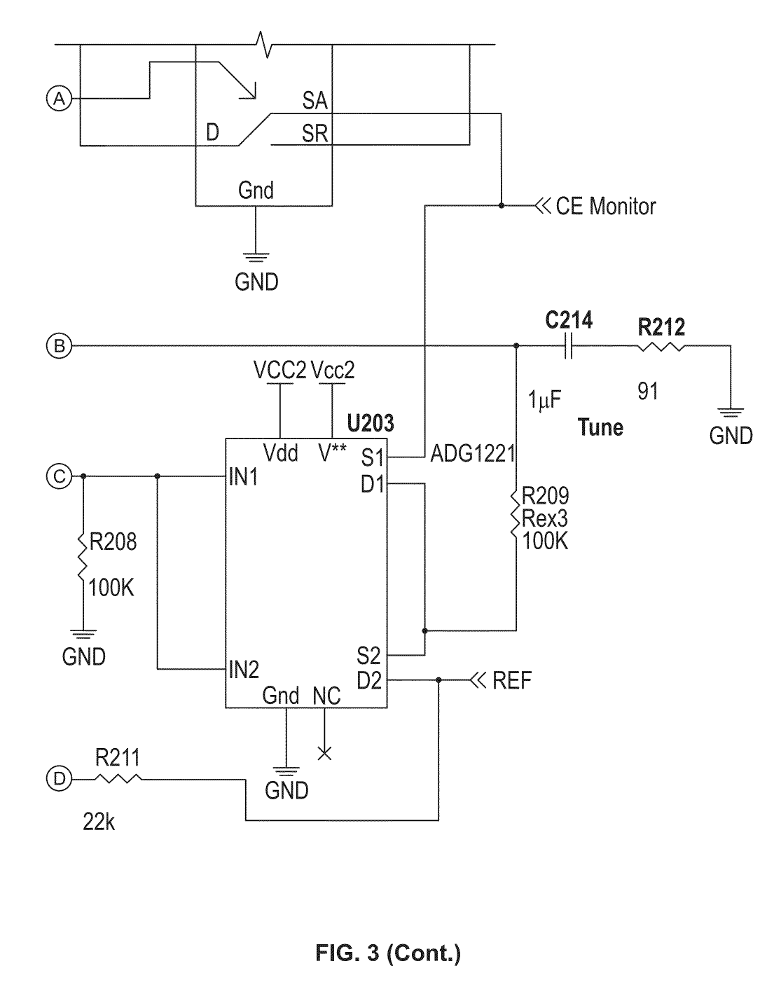

FIG. 2 depicts a block diagram of a transmission line system 200. The transmission line system 200 of FIG. 2 includes a transmission line 202. The transmission line 202 may be the same transmission line 112 highlighted by the dashed box 114 in FIG. 1. Transmission line 202 includes conductor 210 and shield 212. The shield 212 substantially surrounds the conductor 210. The transmission line system 200 of FIG. 2 also includes a first compensation circuit 204, a unity gain buffer 206 and a second compensation circuit 208 coupled between conductor 210 and shield 212. In certain embodiments, the transmission line system 200 of FIG. 2 may include a High-Z buffer (not shown) coupled between the “signal out to instrument” node and the first compensation circuit 204. To provide a suitably buffered and compensated version of the reference signal from the conductor 210 to the outer shield 212, the reference signal from the conductor 210 is measured. The signal is then passed through the High-Z buffer (not shown in FIG. 2). As an example, the High-Z buffer may include a collection of circuit components as shown in FIG. 3 as U204. Next, the first compensation circuit 204 removes the high frequency components of the signal. This prevents the circuit from oscillating due to coupling between the outer shield 212 and the inner conductor 210. The unity gain buffer 206 amplifies the signal, and the second compensation circuit 208 shifts the phase of the signal. Phase-shifting the signal provides an additional stability margin between the second signal (applied to the shield 212) and the first signal (carried by the conductor 210). The modified signal is then applied to the shield 212.

FIG. 3 depicts a circuit diagram of an active shield circuit 300. The REF node is the reference line coupled to the reference electrode. The reference line may be routed to the reference electrode using a coaxial cable where the outer braid of the coaxial cable is connected to the REF Shield node, As previously indicated, in a conventional design, the outer coaxial braid would be grounded. The capacitance created between the grounded braid and center conductor loads the electrode output and slows down detection.

Active shield circuit 300 includes a compensation circuit that may be used to prevent the capacitance between the outer braid of the coaxial cable and the inner conductor from being charged or discharged. Resistor R205 and capacitor C209 may, for example, make up a first compensation circuit, such as first compensation circuit 204 of FIG. 2 which can provide the compensation needed for stability in the system. Unity gain buffer U202 of the circuit in FIG. 3 may function as the unity gain buffer 206 of the transmission system of FIG. 2. Capacitor C214 and resistor R212 make up a second compensation circuit, similar to second compensation circuit 208 of FIG. 2. The second compensation circuit shifts the phase of the output of buffer U204 to prevent positive feedback due to capacitive coupling between the signal on the transmission line (REF) and the signal on the shield (REF Shield). The system of compensation circuits, buffers and other circuit components of FIG. 3 may function to modify a reference signal on a conductor in a transmission line before applying it to the shield of the transmission line. This active shield circuit 300 may have feedback paths (e.g., through the cable capacitance) that could pose the risk of causing instabilities. To prevent such instabilities, components R205, C209, C214 and R212 provide compensation that prevents or reduces oscillations of the circuit. In addition to making the cable capacitance invisible to the electrode, the circuit of FIG. 3 greatly increases electromagnetic compatibility (EMC) performance by driving the outer braid of the coaxial cable from a low impedance source. As a result, external electric field interference is unable to substantially change the potential of that node.

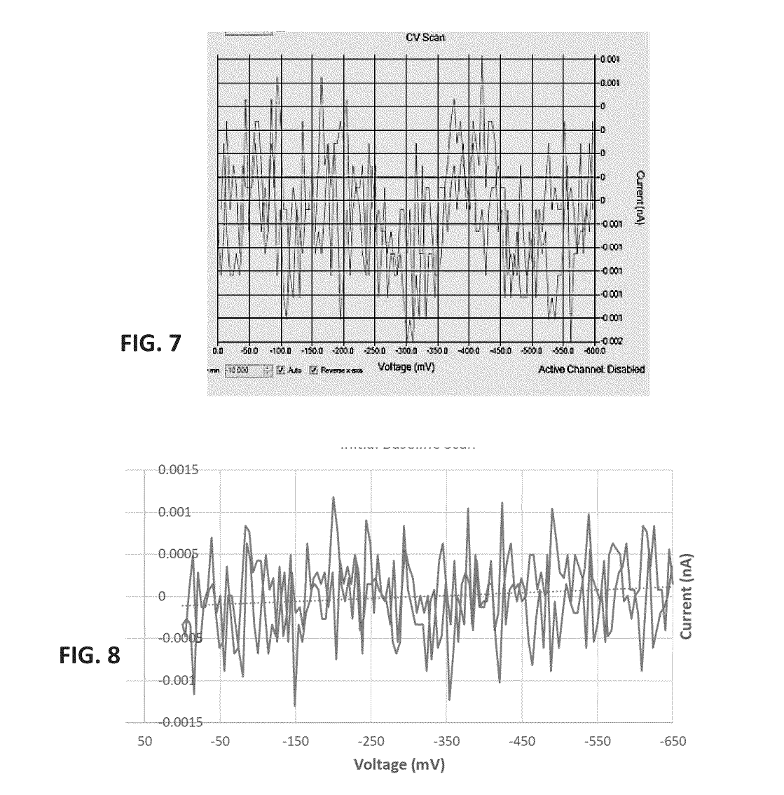

FIG. 7 depicts a voltage-current curve measured without active shielding, and FIG. 8 depicts a voltage-current curve measured with active shielding. FIG. 7 shows that the noise measured when an active shielding system (e.g., active shield circuit 300) is not in use has a RMS of over 600 femtoAmps in the voltage range of 0 to −600V. FIG. 8 shows that the noise measured when an active shielding system (e.g., active shield circuit 300) is used is has a RMS of less than 30 femtoAmps in the voltage range of 0 to −600 mV. Thus, active shielding of a transmission line may significantly reduce the noise in a current signal transmitted on the transmission line.

The systems, circuits, devices, and methods described above may be incorporated in a diagnostic system for detecting the presence or absence of a target marker using electrocatalytic techniques. The active shielding disclosed herein can be used to shield the reference electrode of a potentiostat that applies a voltage to an electrode to detect the presence of a target marker in a solution. Electrochemical techniques including, but not limited to cyclic voltammetry, amperometry, chronoamperometry, differential pulse voltammetry, calorimetry, and potentiometry may be used for detecting a target marker. A brief description of one of these techniques, as applied to the current system, is provided below, it being understood that the electrocatalytic techniques are illustrative and non-limiting and that other techniques can be envisaged for use with the other systems, devices and methods of the current system. Applications of electrocatalytic techniques are described in further detail in U.S. Pat. Nos. 7,361,470 and 7,741,033, and PCT Application No. PCT/US12/024015, which are hereby incorporated by reference herein in their entireties.

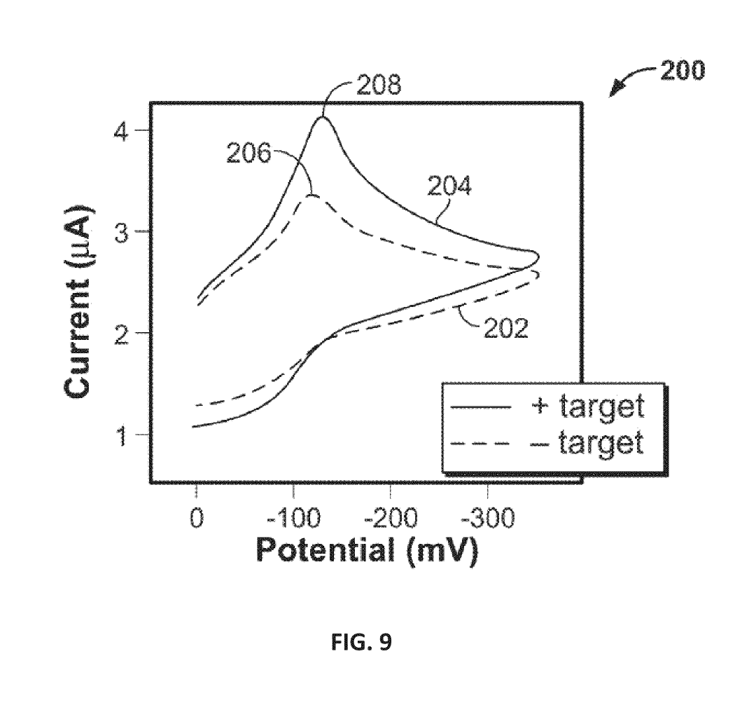

Chart 200 of FIG. 9 depicts representative electrocatalytic detection signals generated using a potentiostat having the active shielding circuit described above. The potentiostat, is used to apply a voltage signal at an electrode. The potentiostat may cycle or ramp the applied voltage between two points, such as from 0 mV to −300 mV and back to 0 mV, while the resultant current is measured. Accordingly, chart 200 depicts the current along the vertical axis at corresponding potentials between 0 mV and −300 mV, along the horizontal axis. Data graph 202 represents a signal measured at an electrode in the absence of a target marker. Data graph 204 represents a signal measured at an electrode in the presence of a target marker. As can be seen on data graph 204, the signal recorded in the presence of the target molecule provides a higher amplitude current signal, particularly when comparing peak 208 with peak 206 located at approximately −100 mV. Accordingly, the presence and absence of the marker can be differentiated. However, the applied voltages are relative to the potential of the reference electrode. Therefore, if electromagnetic interference alters the voltage measured at the reference electrode, the potential applied to the electrodes, and therefore the overall measurement, could be disturbed.

In certain applications, a single electrode or sensor is configured with two or more probes, arranged next to each other, or on top of or in close proximity within the chamber so as to provide target and control marker detection in an even smaller point-of-care size configuration. For example, a single electrode sensor may be coupled to two types of probes, which are configured to hybridize with two different markers. In certain approaches, a single probe is configured to hybridize and detect two markers. In certain approaches, two types of probes may be coupled to an electrode in different ratios. For example, a first probe may be present on the electrode sensor at a ratio of 2:1 to the second probe. Accordingly, the sensor is capable of providing discrete detection of multiple analytes. For example, if the first marker is present, a first discrete signal (e.g., current) magnitude would be generated, if the second marker is present, a second discrete signal magnitude would be generated, if both the first and second marker are present, a third discrete signal magnitude would be generated, and if neither marker is present, a fourth discrete signal magnitude would be generated. Similarly, additional probes could also be implemented for increased numbers of multi-target detection.

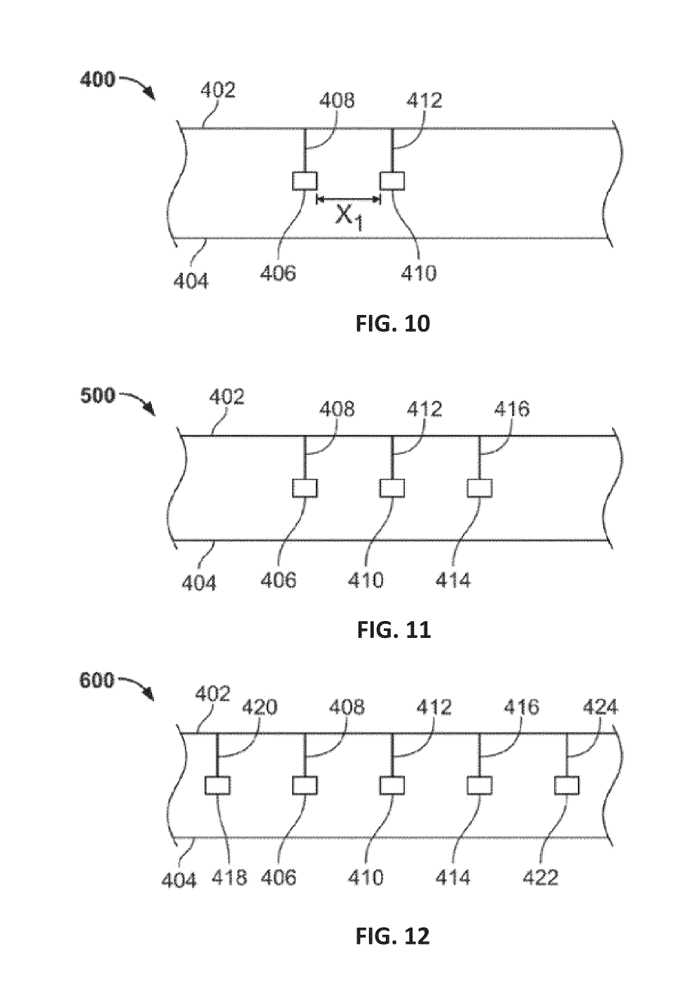

In certain aspects, the sensors and electrodes described herein are integrated into a sensing or analysis chamber, for example in a point-of-care device, to analyze a sample from a biological host. FIG. 10 depicts an analysis chamber 400 with a pathogen sensor 406 and a host sensor 410. The chamber 400 includes walls 402 and 404 that form a space with which a sample is retained and analyzed at sensors 406 and 410. Pathogen sensor 406 includes a conductive trace 408 to connect the sensor 406 to controlling instrumentation such as a potentiostat. Host sensor 410 is also connected to external or controlling instrumentation with a conductive trace 412. Pathogen sensor 406 and host sensor 410 are separated by a distance X.

In certain aspects, the systems, methods, and devices described herein are integrated into a sensing or analysis chamber, for example in a point-of-care device, to analyze a sample from a biological host. FIG. 11 depicts an analysis chamber 400 with a pathogen sensor 406 and a host sensor 410. The chamber 400 includes walls 402 and 404 that form a space with which a sample is retained and analyzed at sensors 406 and 410. Pathogen sensor 406 includes a conductive trace 408 to connect the sensor 406 to controlling instrumentation such as a potentiostat. Host sensor 410 is also connected to external or controlling instrumentation with a conductive trace 412. Pathogen sensor 406 and host sensor 410 are separated by a distance X₁.

The pathogen sensor 406 is used to determine whether or not the marker is present in the sample. Although not depicted in FIG. 11, pathogen sensor 406 includes a probe configured to couple to a target marker from a pathogen. In certain approaches, the probe is a peptide nucleic acid probe. For example, the probe coupled to the pathogen sensor 406 may include a nucleotide sequence that is complementary to a nucleotide sequence from a pathogen which is unique to that pathogen.

The host sensor 410 includes a probe configured to couple to a host marker. The host marker is an endogenous element from a biological host, such as a DNA sequence, RNA sequence, or peptide. For example, the probe coupled to host sensor 410 may be configured with a nucleotide sequence that hybridizes with a nucleotide sequence unique to the human genome. In certain approaches, the probe for the host marker is a peptide nucleic acid probe. Preferably, the host marker is present in every biological sample taken from a human patient, and therefore can serve as a positive, internal control for the analysis process, Accordingly, detection of the host marker at host sensor 410 serves as a control for the assay. Specifically, detection of the host marker confirms that the sample was taken correctly from the host (e.g., a patient), that the sample was processed correctly, and that hybridization of the probe and marker in the analysis chamber has taken place successfully. If any part of the assay fails, and the host marker is not detected at host sensor 410, the assay is considered indeterminate.

The pathogen sensor 406 and host sensor 410 operate using the electrocatalytic methods described in detail in U.S. Pat. Nos. 7,361,470 and 7,741,033, and PCT Application No. PCT/US12/024015 (although such sensors and the internal control techniques discussed herein could also be applied in other diagnostic methods). FIG. 11 depicts only two sensors, but any number of sensors may be used For example, chamber 400 may include a plurality of pathogen sensors 406 and a plurality of host sensors 410. When a plurality of sensors is used, each sensor may optionally be configured to sense a different target marker in order to detect the presence or absence of different pathogens, different hosts, or different parts of the same pathogen or the same host. In alternative approaches, a plurality of pathogen sensors 406 is used, but each pathogen sensor is configured to sense the same target marker in order to provide additional verification of the presence or absence of that target marker. Similarly, a plurality of host sensors 410 may also be used with each sensor being configured to detect the presence or absence of the same host target marker to provide additional verification of the measurement.

FIG. 12 depicts an additional embodiment of an analysis chamber. Chamber 500 is similar to chamber 400 in that it includes walls 402 and 404, pathogen sensor 406 and host sensor 410. Chamber 500 additionally includes a non-sense sensor 414. Similar to pathogen sensor 406 and host sensor 410, non-sense sensor 414 is electrically coupled to controlling instrumentation, such as a potentiostat, with a conductive trace 416. The non-sense sensor 414 may also include an electrode, such as a nanostructured microelectrode. Non-sense sensor 414 includes a probe, such as probe 106. In certain approaches, the non-sense probe is a peptide nucleic acid probe. The non-sense probe, however, is not configured to mate with a marker from the pathogen or the biological host. Instead, the probe coupled to non-sense sensor 414 has a structure, such as a nucleotide sequence, which is not found in either the pathogen or the biological host. The non-sense sensor serves as an additional control to verify that the conditions within analysis chamber 500 can provide accurate sensing results. Non-sense sensor 414 tests fir nonspecific binding. Nonspecific binding of a nucleotide sequence may occur under inappropriate hybridization conditions in chamber 500. For example, nonspecific binding may occur when the pH, ionic strength, or temperature are not appropriate for accurate testing. If binding occurs at non-sense sensor 414, then other nonspecific binding may take place at pathogen sensor 406 and the host sensor 410, and therefore the assay would be inaccurate. The non-sense sensor 414 is thereby able to act as an additional control for testing conditions. The non-sense sensor 414 may also function using electrocatalytic techniques as previously described. Although FIG. 12 depicts three sensors, any number of sensors could be used. Sensors 406, 410, and 414 are arranged in chamber 500 in a linear arrangement. However, sensors 406, 410, and 414 may also be arranged in other patterns.

FIG. 13 depicts an additional embodiment of an analysis chamber 600 which is similar to chambers 400 and 500 previously described. FIG. 13 also depicts a reference electrode 418 and a counter electrode 422. The reference electrode 418 and counter electrode 422 are connected to the controlling instrumentation (e.g., a potentiostat having shielding circuit 300) by conductive traces 420 and 424, respectively. All or part of the conductive trace 420 may be shielded using the active shielding systems, methods, and devices described above. The reference electrode 418 and counter electrode 422 are used in the electrocatalytic measurements. The reference electrode 418 serves as a reference for applying a voltage at any of the sensors 406, 410, and 414. When a voltage is applied at a sensor (e.g., sensors 406, 410 and 414), the current generated flows through a sensor (e.g., sensors 406, 410, and 414), through the hybridized complex of the probe and target, through the sample, and through the counter electrode 422.

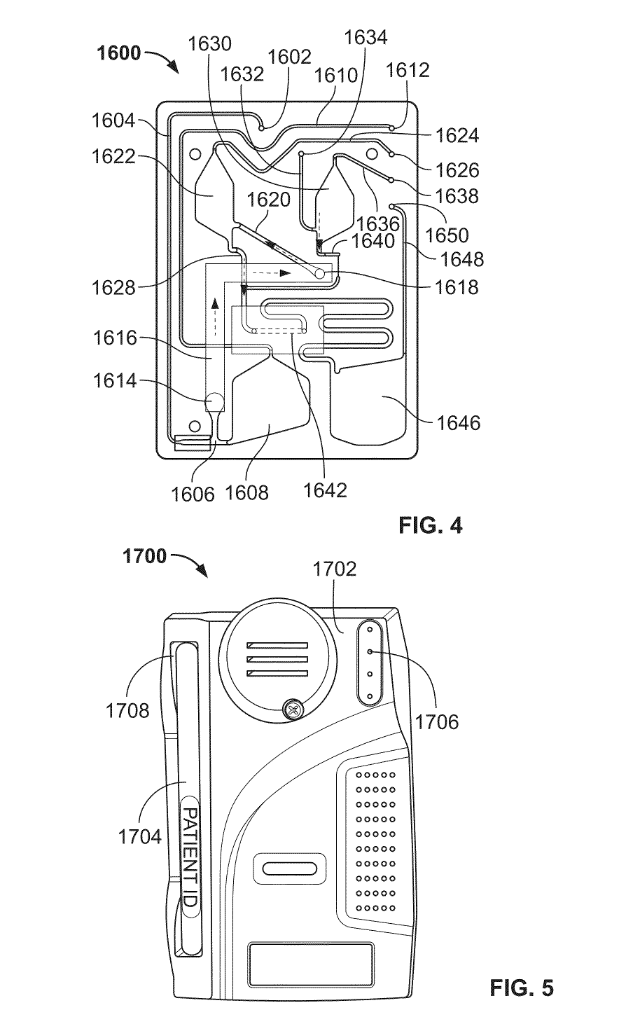

The systems, devices, methods, and all embodiments described above may be incorporated into a cartridge to prepare a sample for analysis and perform a detection analysis. FIG. 4 depicts a cartridge system 1600 for receiving, preparing, and analyzing a biological sample. For example, cartridge system 1600 may be configured to remove a portion of a biological sample from a sample collector or swab, transport the sample to a lysis zone where a lysis and fragmentation procedure are performed, and transport the sample to an analysis chamber for determining the presence of various markers and to determine a disease state of a biological host,

Cartridges may use any appropriate formats, materials, and size scales for sample preparation and sample analysis. In certain approaches, cartridges use microfluidic channels and chambers. In certain approaches, the cartridges use macrofluidic channels and chambers. Cartridges may be single layer devices or multilayer devices. Methods of fabrication include, but are not limited to, photolithography, machining, micromachining, molding, and embossing.

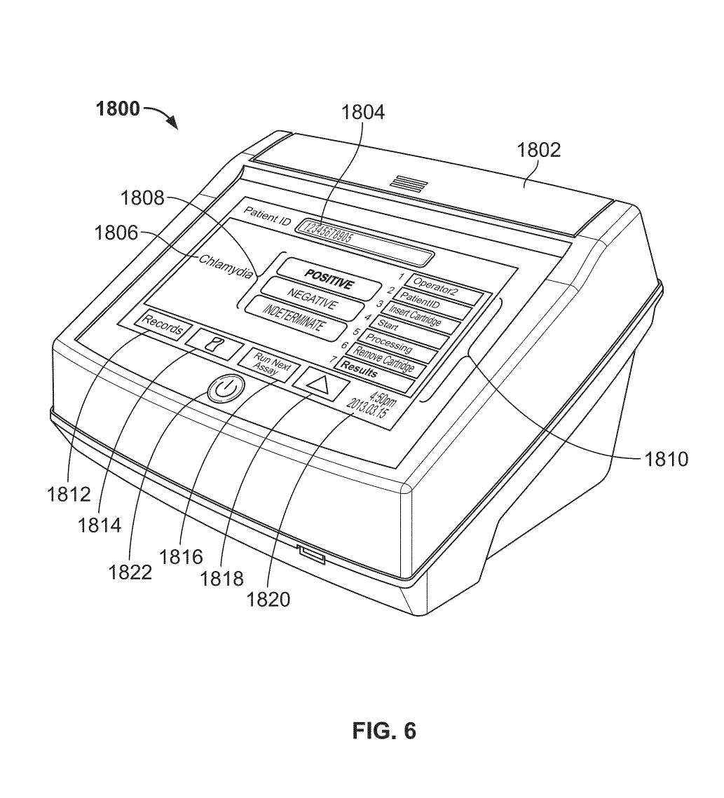

FIG. 6 depicts an automated testing system to provide ease of processing and analyzing a sample. System 1800 may include a cartridge receiver 1802 for receiving a cartridge, such as cartridge 1700. System 1800 may include other buttons, controls, and indicators. For example, indicator 1804 is a patient ID indicator, which may be typed in manually by a user, or read automatically from cartridge 1700 or cartridge container 1704. System 1800 may include a “Records” button 1812 to allow a user to access or record relevant patient record information, “Print” button 1814 to print results, “Run Next Assay” button 1818 to start processing an assay, “Selector” button 1818 to select process steps or otherwise control system 1800, and “Power” button 1822 to turn the system on or off. Other buttons and controls may also be provided to assist in using system 1800. System 1800 may include process indicators 1810 to provide instructions or to indicate progress of the sample analysis. System 1800 includes a test type indicator 1806 and results indicator 1808. For example, system 1800 is currently testing for Chlamydia as shown by indicator 1806, and the test has resulted in a positive result, as shown by indicator 1808. System 1800 may include other indicators as appropriate, such as time and date indicator 1820 to improve system functionality.

The foregoing is merely illustrative of the principles of the disclosure, and the systems, devices, and methods can be practiced by other than the described embodiments, which are presented for the purposes of illustration and not of limitation. It is to be understood that the systems, devices, and methods disclosed herein, while shown for use in detection systems for bacteria, and specifically, for Chlamydia Trachomatis, may be applied to systems, devices, and methods to be used in other applications including, but not limited to, detection of other bacteria, viruses, fungi, prions, plant matter, animal matter, protein, RNA sequences, DNA sequences, as well as cancer screening and genetic testing, including screening for genetic disorders.

Variations and modifications will occur to those of skill in the art after reviewing this disclosure. The disclosed features may be implemented, in any combination and subcombination (including multiple dependent combinations and subcombinations), with one or more other features described herein. The various features described or illustrated above, including any components thereof, may be combined or integrated in other systems. Moreover, certain features may be omitted or not implemented.

Examples of changes, substitutions, and alterations are ascertainable by one skilled in the art and could be made without departing from the scope of the information disclosed herein. All references cited are hereby incorporated by reference herein in their entireties and made part of this application.

1. A method implemented by a circuit for shielding an electrode from interference, the method comprising:
applying a first signal to a conductor coupled to the electrode;
applying a second signal to a shield substantially surrounding the conductor;
blocking electrical interference to the first signal; and
increasing an effective impedance on the electrode coupled to the conductor.

2. The method of claim 1, wherein the second signal is a compensated version of the first signal.

3. The method of claim 1, wherein the second signal is buffered.

4. The method of claim 1, wherein the second signal is created using compensation circuitry.

5. The method of claim 4, wherein the compensation circuitry is configured to:
measure the first signal on the conductor;
amplify the first signal;
remove at least one high frequency component from the first signal; and
phase shift the first signal.

6. The method of claim 1, further comprising substantially reducing a potential difference between the conductor and the shield.

7. The method of claim 6, wherein substantially reducing a potential difference between the conductor and the shield comprises reducing the potential difference to approximately zero.

8. The method of claim 1, wherein the second signal is applied by a low impedance source.

9. A method for detecting a target in a sample using a point-of-care diagnostic device, wherein the diagnostic device includes a potentiostat that uses the method according to claim 1, thereby providing active shielding for one or more reference electrodes in the potentiostat.

10. The method of any one of the preceding claims claim 1, wherein the signal path comprises a reference electrode in a potentiostat.

11. The method of claim 1, wherein the signal path comprises a high impedance transducer interface.

12. A signal transmission system comprising:
a transmission line including a conductor and a shield substantially surrounding the conductor;
first and second compensation circuits coupled between the conductor and the shield; and
a unity gain buffer coupled between the first and second compensation circuits.

13. The signal transmission system of claim 12, further comprising an electrode coupled to the conductor.

14. The signal transmission system of claim 13, wherein the electrode is a reference electrode.

15. The signal transmission system of claim 12, wherein the first compensation circuit reduces high frequency gain to reduce positive feedback caused by coupling in the shielded transmission line.

16. The signal transmission system of claim 12, wherein the first compensation circuit provides phase shift to reduce positive feedback caused by coupling in the shielded transmission line.

17. The signal transmission system of claim 12, wherein the second compensation circuit phase shifts the first signal to reduce positive feedback caused by coupling in the shielded transmission line.

18. The signal transmission system of claim 12, wherein the transmission line is a coaxial cable.

19. The signal transmission system of claim 12, wherein the shield comprises a braided cylinder.

20. The signal transmission system of claim 12, wherein the shield comprises a faraday cage.

21. A point-of-care diagnostic device, wherein the diagnostic device includes a potentiostat that includes the signal transmission system according to claim 12, thereby providing active shielding for one or more reference electrodes in the potentiostat.

22. A point-of-care diagnostic device having:
a potentiostat;
an analysis chamber having a reference electrode connected to the potentiostat by a first conductive trace; and
a counter electrode connected to the potentiostat by a second conductive trace, wherein part of the first conductive trace is shielded using the active shielding method of claim 1.
